(19) United States
(12) Patent Application Publication
(10) Pub. No.: US 2026/0190803 A1
(43) Pub. Date: Jul. 2, 2026

(54) DISPLAY PANEL, METHOD FOR MANUFACTURING DISPLAY PANEL, AND DISPLAY DEVICE

(71) Applicants: Yunnan Invensight Optoelectronics Technology Co., Ltd., Yunnan (CN); BOE Technology Group Co., Ltd., Beijing (CN)

(72) Inventors: Shipeng LI, Beijing (CN); Lingang WEN, Beijing (CN); Qingshan SHAN, Beijing (CN); Weixiong FENG, Beijing (CN); Yinhu HUANG, Beijing (CN); Dacheng ZHANG, Beijing (CN); Jianming ZOU, Beijing (CN)

(73) Assignees: Yunnan Invensight Optoelectronics Technology Co., Ltd., Yunnan (CN); BOE Technology Group Co., Ltd., Beijing (CN)

(21) Appl. No.: 18/837,637

(22) PCT Filed: Oct. 11, 2023
(86) PCT No.: PCT/CN2023/124041

§ 371 Date: Aug. 12, 2024

(51) Int. Cl. H10K 59/80; H10K 59/12; H10K 59/38

(52) U.S. Cl. CPC H10K 59/879; H10K 59/1201; H10K 59/38; H10K 59/873

(57) ABSTRACT

The present disclosure provides a display panel. The display includes: a base, a plurality of light-emitting units disposed on the base, and a plurality of light-transmitting protruding structures, wherein the plurality of protruding structures are disposed on a side of the plurality of light-emitting units away from the base, and the protruding structure has a center region and an edge region outside the center region, a roughness of the center region being smaller than a roughness of the edge region, and a center of an orthographic projection of the protruding structure on the base being within an orthographic projection of the center region on the base.

### CROSS-REFERENCE TO RELATED APPLICATION

This application is a U.S. national stage of international application No. PCT/CN2023/124041, filed on Oct. 11, 2023, the disclosure of which is incorporated herein by reference in its entirety.

### TECHNICAL FIELD

The present disclosure relates to the field of display technologies, and in particular, relates to a display panel, a method for manufacturing a display panel, and a display device.

### BACKGROUND

A display panel is a device having an image display function.

A display panel includes a base, a plurality of light-emitting units disposed on the base, and an encapsulation layer, a color adhesive layer, and a plurality of protruding structures that are sequentially laminated on a side of the plurality of light-emitting units away from the base. The protruding structures correspond to the light-emitting units, and the protruding structure can converge light emitted from the corresponding light-emitting unit to enhance the brightness of the display panel.

### SUMMARY

Embodiments of the present disclosure provide a display panel, a method for manufacturing a display panel, and a display device. The technical solutions are as follows.

According to some embodiments the present disclosure, a display panel is provided. The display panel includes:
a base;
a plurality of light-emitting units disposed on the base; and
a plurality of light-transmitting protruding structures, wherein the plurality of protruding structures are disposed on a side of the plurality of light-emitting units away from the base, and the protruding structure has a center region and an edge region outside the center region, a roughness of the center region being smaller than a roughness of the edge region, and a center of an orthographic projection of the protruding structure on the base being within an orthographic projection of the center region on the base.

In some embodiments, a roughness of the protruding structure decreases sequentially along a light-exiting direction of the light-emitting unit, the center region is a region with a roughness smaller than a target roughness, and the edge region is a region with a roughness greater than or equal to the target roughness.

In some embodiments, the display panel further includes: a color film layer; wherein the color film layer is disposed on the side of the plurality of light-emitting units away from the base, and the plurality of protruding structures are disposed on the color film layer;
the color film layer includes a plurality of color resist blocks, wherein the protruding structure corresponds to at least one of the plurality of color resist blocks, and the orthographic projection of the protruding structure on the base is overlapped with an orthographic projection of a corresponding color resist block on the base.

In some embodiments, a plurality of first pits are formed in the color film layer; wherein the first pit is disposed between two adjacent protruding structures of the plurality of protruding structures disposed on the color film layer.

In some embodiments, the plurality of color resist blocks in the color film layer include at least three colors of color resist blocks; wherein the first pit is disposed in a junction region of two adjacent color resist blocks of the three colors of color resist blocks, and the first pits in different junction regions of two colors of color resist blocks have different depths, wherein the junction region is a region including a junction of the two adjacent color resist blocks.

In some embodiments, the first pit is an arcuate first pit.

In some embodiments, the display panel further includes: a plurality of first etch-resistant blocks; wherein the first etch-resistant block is disposed between two adjacent protruding structures of the plurality of protruding structures disposed on the color film layer.

In some embodiments, a material of the first etch-resistant block includes a light-shielding material.

In some embodiments, a surface of the first etch-resistant block away from the base is an arcuate surface recessed towards the base;
the display panel further includes: a light-transmitting layer, wherein the light-transmitting layer is disposed on the surface of the first etch-resistant block away from the base, and a refractive index of the first etch-resistant block is less than a refractive index of the light-transmitting layer.

In some embodiments, the protruding structure includes a plurality of micro protruding structures disposed in the edge region.

In some embodiments, a material of the protruding structure includes a color resist material, and the plurality of protruding structures are reused as a color film layer.

In some embodiments, the plurality of protruding structures include at least three colors of color resist materials, the roughness of the protruding structure corresponds to a color of the color resist material, and different colors corresponding to different roughnesses.

In some embodiments, the display panel further includes: an encapsulation layer; wherein the encapsulation layer is disposed on the side of the plurality of light-emitting units away from the base, and the plurality of protruding structures are disposed on the encapsulation layer.

In some embodiments, a plurality of second pits are formed in the encapsulation layer; wherein the second pit is disposed between two adjacent protruding structures of the plurality of protruding structures disposed on the encapsulation layer.

In some embodiments, an edge of the second pit is smoothly connected to an edge of the protruding structure.

In some embodiments, the plurality of color resist blocks in the color film layer include at least three colors of color resist blocks, and the second pits disposed between different two colors of color resist blocks have different depths.

In some embodiments, the display panel further includes: a plurality of second etch-resistant blocks; wherein the second etch-resistant block is disposed between two adjacent protruding structures of the plurality of protruding structures.

In some embodiments, a material of the second etch-resistant block includes a light-shielding material.

In some embodiments, the protruding structure is a convex lens, and a size of the protruding structure is negatively correlated with an average roughness of the edge region.

In some embodiments, the protruding structure is a trapezoidal protrusion, wherein an upper surface of the trapezoidal protrusion is on a side of a lower surface away from the base.

According to some embodiments of the present disclosure, a method for manufacturing a display panel is provided. The method includes:
acquiring a base;
forming a plurality of light-emitting units on the base;
forming a plurality of light-transmitting protruding structures on the base on which the plurality of light-emitting units are formed, wherein the plurality of protruding structures are disposed on a side of the plurality of light-emitting units away from the base, and the protruding structure has a center region and an edge region outside the center region, a roughness of the center region being smaller than a roughness of the edge region, and a center of an orthographic projection of the protruding structure on the base being within an orthographic projection of the center region on the base.

In some embodiments, forming the plurality of light-transmitting protruding structures on the base on which the plurality of light-emitting units are formed includes:
forming a light-transmitting material layer on the base on which the plurality of light-emitting units are formed;
forming a plurality of protruding structure models on the light-transmitting material layer;
processing the light-transmitting material layer into the plurality of protruding structures by transferring the plurality of protruding structure models to the light-transmitting material layer by a dry-etching process and adjusting the roughness of the center region and the roughness of the edge region by adjusting an oxygen flow in a dry-etching environment.

According to some embodiments of the present disclosure, a display device is provided. The display device includes: a power supply assembly and any one of the above display panels.

### BRIEF DESCRIPTION OF DRAWINGS

For clearer descriptions of the technical solutions in the embodiments of the present disclosure, the following briefly introduces the accompanying drawings required for describing the embodiments. The accompanying drawings in the following descriptions show merely some embodiments of the present disclosure, and persons of ordinary skill in the art may still derive other drawings from these accompanying drawings without creative effort.

FIG. 1 is a schematic structural diagram of a display panel;

FIG. 2 is a schematic diagram of light emission of the display panel provided in FIG. 1;

FIG. 3 is a schematic structural diagram of a display panel according to some embodiments of the present disclosure;

FIG. 4 is a schematic diagram of light emission of the display panel provided in FIG. 3;

FIG. 5 is a schematic diagram of a top view structure of a protruding structure according to some embodiments of the present disclosure;

FIG. 6 is a schematic structural diagram of another display panel according to some embodiments of the present disclosure;

FIG. 7 is a schematic diagram of a top view structure of a display panel according to some embodiments of the present disclosure;

FIG. 8 is a schematic structural diagram of another display panel according to some embodiments of the present disclosure;

FIG. 9 is a schematic structural diagram of another display panel according to some embodiments of the present disclosure;

FIG. 10 is a schematic structural diagram of another display panel according to some embodiments of the present disclosure;

FIG. 11 is a schematic structural diagram of another display panel according to some embodiments of the present disclosure;

FIG. 12 is a schematic structural diagram of another display panel according to some embodiments of the present disclosure;

FIG. 13 is a schematic structural diagram of another display panel according to some embodiments of the present disclosure;

FIG. 14 is a schematic structural diagram of another display panel according to some embodiments of the present disclosure;

FIG. 15 is a schematic structural diagram of another display panel according to some embodiments of the present disclosure;

FIG. 16 is a schematic structural diagram of another display panel according to some embodiments of the present disclosure;

FIG. 17 is a schematic structural diagram of another display panel according to some embodiments of the present disclosure;

FIG. 18 is a schematic structural diagram of another display panel according to some embodiments of the present disclosure;

FIG. 19 is a schematic diagram of light emission of the display panel provided in FIG. 18;

FIG. 20 is a flowchart of a method for manufacturing a display panel according to some embodiments of the present disclosure;

FIG. 21 is a flowchart of another method for manufacturing a display panel according to some embodiments of the present disclosure;

FIG. 22 is a schematic diagram of a manufacturing process of a protruding structure according to some embodiments of the present disclosure;

FIG. 23 is a schematic diagram of a manufacturing process of another protruding structure according to some embodiments of the present disclosure;

FIG. 24 is a flowchart of another method for manufacturing a display panel according to some embodiments of the present disclosure; and

FIG. 25 is a schematic diagram of a manufacturing process of another protruding structure according to some embodiments of the present disclosure.

Specific embodiments of the present disclosure have been shown by means of the foregoing accompanying drawings, and will be described in more detail below. The accompanying drawings and textual descriptions are not intended to limit the scope of the concepts of the present disclosure in any way, but rather to illustrate the concepts of the present disclosure to those skilled in the art by reference to the specific embodiments.

### DETAILED DESCRIPTION

To make the objectives, technical solutions, and advantages of the present disclosure clearer, the embodiments of the present disclosure are further described in detail below with reference to the accompanying drawings.

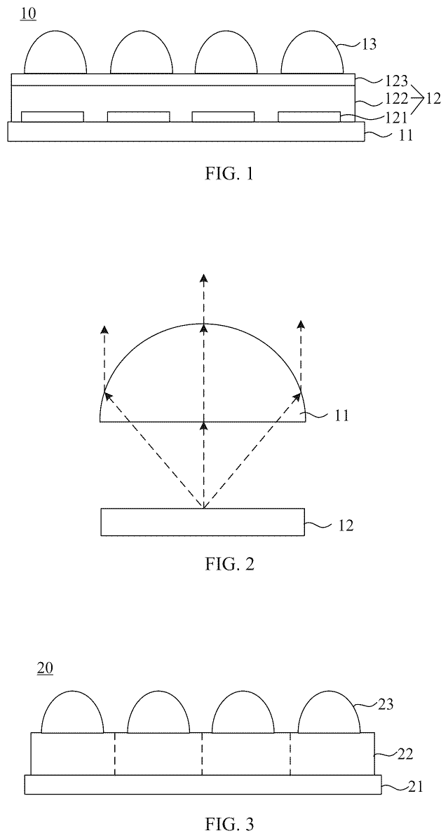

FIG. 1 shows a schematic structural diagram of a display panel, and FIG. 2 is a schematic diagram of light emission of the display panel provided in FIG. 1. Referring to FIG. 1 and FIG. 2, the display panel 10 includes a base 11, a plurality of light-emitting units 12 disposed on the base 11, and a plurality of light-transmitting protruding structures 13 disposed on the side of the plurality of light-emitting units 12 away from the base 11. The light-emitting units 12 include a first electrode layer 121, a light-emitting layer 122, and a second electrode layer 123 that are sequentially laminated. The protruding structure 13 corresponds to the light-emitting unit 12, and the protruding structure 13 can converge light emitted from the corresponding light-emitting unit 12. After being converged by the protruding structure 13, the light-exiting direction of the light emitted from the light-emitting unit 12 is perpendicular to the base 11. Thus, the viewing angle of the display panel is small, and when a user views the display panel at a big viewing angle, the brightness is low and the user experience is poor.

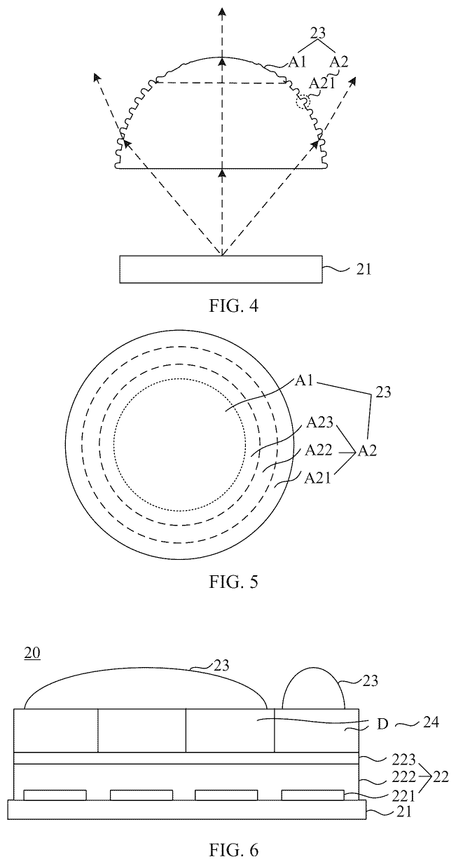

Some embodiments of the present disclosure provide a display panel. Referring to FIG. 3, FIG. 4 and FIG. 5, FIG. 3 is a schematic structural diagram of a display panel according to some embodiments of the present disclosure, FIG. 4 is a schematic diagram of light emission of the display panel provided in FIG. 3, and FIG. 5 is a schematic diagram of a top view structure of a protruding structure in the display panel provided in FIG. 3. The display panel 20 includes a base 21, a plurality of light-emitting units 22 disposed on the base 21, and a plurality of light-transmitting protruding structures 23 disposed on the side of the plurality of light-emitting units 22 away from the base 21. The protruding structure 23 has a center region Al and an edge region A2 outside the center region A1. A roughness of the center region Al is smaller than a roughness of the edge region A2, and a center of an orthographic projection of the protruding structure 23 on the base 21 is within an orthographic projection of the center region Al on the base 21.

It should be noted that the dotted lines in the light-emitting units 22 are intended to clearly illustrate the plurality of light-emitting units and are not actual structures. FIG. 3 merely shows four light-emitting units 22 for an illustrative description, and the number of the light-emitting units is not limited in the embodiments of the present disclosure.

In summary, the embodiments of the present disclosure provide a display panel including a base, a plurality of light-emitting units, and a plurality of light-transmitting protruding structures. The protruding structure has a center region and an edge region outside the center region, and the roughness of the center region is smaller than the roughness of the edge region. With this structure, light emitted from the plurality of light-emitting units can be converged by the protruding structures. Because the protruding structure has a bigger roughness in the edge region, the light-converging capability of the edge region can be reduced, and the viewing angle of the display panel can be increased under the premise of ensuring a certain brightness in the front viewing angle direction, thereby solving the problem of the small viewing angle of the display panel in the related art and achieving the effect of improving the viewing angle of the display panel.

Referring to FIG. 3, FIG. 4, and FIG. 5, the roughness of the center region A1 is an average roughness of the surface of the side, away from the base 21, of the center region A1 or a maximum value of the roughnesses at various positions of the surface of the side, away from the base 21, of the center region A1; and the roughness of the edge region A2 is an average roughness of the surface of the side, away from the base 21, of the edge region A2 or a maximum value of the roughnesses at various positions of the surface of the side, away from the base 21, of the edge region A2. The roughness may be measured using an atomic force microscope (AFM), and the calculated roughness value is the distance from the peak to the valley of the surface of the rough region.

The smaller the roughness, the smoother the surface of the protruding structure, the better the light-converging effect of the protruding structure, and the smaller the angle between light and a vertical direction perpendicular to the base. The greater the roughness, the rougher the surface of the protruding structure, the poorer the light-converging effect of the protruding structure, the bigger the angle between light and the vertical direction perpendicular to the base, and the bigger the viewing angle. Because the roughness of the center region A1 is smaller than the roughness of the edge region A2, the center region A1 is smoother than the edge region A2. Therefore, the center region A1 makes the angle between the light and the vertical direction perpendicular to the base smaller, thereby ensuring a certain brightness in the front viewing angle direction; and the edge region A2 makes the angle between the light and the vertical direction perpendicular to the base bigger, thereby increasing the viewing angle and ensuring the brightness at a big viewing angle. The bigger the ratio of the light directed to the front viewing angle to all light, the higher the brightness in the front viewing angle direction. The center region A1 and the edge region A2 of the protruding structure 23 both have a certain light-converging effect, the center region A1 with a smaller roughness can converge light to the front viewing angle direction, and the edge region A2 with a greater roughness can converge light to directions other than the front viewing angle direction, thereby increasing the viewing angle.

In some embodiments, the protruding structure includes a plurality of micro protruding structures disposed in the edge region. Referring to FIG. 4, the protruding structure 23 includes a plurality of micro protruding structures A21 in the edge region A2. The plurality of micro protruding structures A21 can increase the roughness of the edge region A2, and can increase the angle between the light and the vertical direction perpendicular to the base, thereby increasing the viewing angle and ensuring the brightness at a bigger viewing angle. In some embodiments, the height of the micro protruding structure A21 is in the range of 5 nm to 50 nm. In addition, the protruding structure 23 does not include the plurality of micro protruding structures A21 in the center region A1, which helps reduce the roughness of the center region A1 and improve the light-converging capability of the center region A1.

The display panel according to the embodiments of the present disclosure may be an organic light-emitting diode (OLED) display panel. For example, the display panel according to the embodiments of the present disclosure is a micro OLED display panel. In the micro OLED display panel, the base of the light-emitting unit is a silicon wafer, and the plurality of light-emitting units include a first electrode layer, a light-emitting layer, and a second electrode layer. The first electrode layer and the second electrode layer cooperate with each other to drive the light-emitting layer. The first electrode layer is an anode, the second electrode layer is a cathode, and the light-emitting layer is an organic light-emitting layer.

In some embodiments, the roughness of the protruding structure decreases sequentially along the light-exiting direction of the light-emitting unit. The center region is a region with a roughness smaller than a target roughness, and the edge region is a region with a roughness greater than or equal to the target roughness. Referring to FIG. 3, FIG. 4, and FIG. 5, the edge region A2 of the protruding structure 23 includes a first edge region A21, a second edge region A22, and a third edge region A23 that are sequentially arranged along the light-exiting direction of the light-emitting unit. The roughness of the first edge region A21 is greater than the roughness of the second edge region A22, the roughness of the second edge region A22 is greater than the roughness of the third edge region A23, and the roughness of the third edge region A23 is greater than the roughness of the center region A1. The target roughness is a desired roughness acquired according to the requirements on the brightness and viewing angle of a product. The bigger the required viewing angle of the product, the greater the target roughness, the higher the required brightness at the front viewing angle of the product, and the smaller the target roughness. The roughness of the upper surface of the side, away from the base 21, of the protruding structure 23 is measured and calculated using an AFM, and is compared with the target roughness, so as to differentiate between the center region A1 and the edge region A2 of the protruding structure 23.

In some embodiments, the target roughness is 50 nm, the center region A1 is a region with a roughness smaller than 50 nm, and the edge region A2 is a region with a roughness greater than or equal to 50 nm. Additionally, in order to prevent the roughness of the edge region A2 from being too big to affect the display effect, the roughness of the edge region is in the range of 50 nm to 150 nm.

The protruding structure is manufactured by transferring a shape of a protruding structure model to a light-transmitting material layer by an etching process. For example, the etching process includes a dry-etching process, and the material of the light-transmitting material layer includes polydimethylsiloxane (PDMS), polymethyl methacrylate (PMMA), and silicon dioxide (SiO₂). The roughness of the center region and the roughness of the edge region are adjusted by adjusting an oxygen flow in the dry-etching environment so as to match the product requirements. The bigger the oxygen flow, the larger the over-etching amount of the protruding structure, and the greater the roughness of the center region and the roughness of the edge region of the protruding structure. Since the thickness of the protruding structure model in the edge region is less than the thickness of the protruding structure model in the center region, the over-etching amount of the light-transmitting material layer in the edge region is larger than the over-etching amount of the light-transmitting material layer in the center region, that is, the edge region is subjected to more etching, and the manufactured protruding structure has a greater roughness in the edge region than in the center region. The used oxygen flow may also be determined by calculating an etching selectivity ratio of the material of the protruding structure model to the material of the light-transmitting material layer, and the etching selectivity ratio is a ratio of an etching rate of the material of the protruding structure model to an etching rate of the material of the light-transmitting material layer. The bigger the etching selectivity ratio, the faster the etching rate of the protruding structure model, the larger the over-etching amount of the light-transmitting material layer, and the bigger the oxygen flow to be used, which is not limited in the embodiments of the present disclosure.

The display panel according to the embodiments of the present disclosure further includes a color film layer. Referring to FIG. 6, which is a schematic structural diagram of a display panel including a color film layer, the display panel 20 includes a base 21, a plurality of light-emitting units 22, a plurality of light-transmitting protruding structures 23, and a color film layer 24. The plurality of light-emitting units include a first electrode layer 221, a light-emitting layer 222, and a second electrode layer 223.

The color film layer 24 is disposed on the side of the plurality of light-emitting units 22 away from the base 21, the plurality of protruding structures 23 are disposed on the color film layer 24, and the color film layer 24 includes a plurality of color resist blocks D. The color film layer 24 filters the light generated by the light-emitting units 22, thereby acquiring light of the same color as the corresponding color resist blocks D in the color film layer 24. For example, different light-emitting units 22 emit different colors of light, each light-emitting unit 22 has the same color as the corresponding color resist block D, and the corresponding color resist block D can filter light to improve the purity of the color of the light. Alternatively, the light-emitting units 22 emit white light, and the color resist block D corresponding to each light-emitting unit 22 can filter the white light into light of the same color as the color resist block D, e.g., red, blue, or green.

The protruding structure 23 corresponds to at least one of the plurality of color resist blocks D, i.e., each protruding structure 23 corresponds to one or more color resist blocks D. In some embodiments, each protruding structure 23 corresponds to one color resist block D, or each protruding structure 23 corresponds to three color resist blocks D, which is not limited in the present disclosure.

The orthographic projection of the protruding structure 23 on the base 21 is overlapped with the orthographic projection of the corresponding color resist block D on the base 21, and then a portion of the protruding structure 23 faces the corresponding color resist block D. Therefore, colored light acquired after light is filtered by the color film layer 24 can be collected and converged by the protruding structure 23. In some embodiments, the center of the protruding structure 23 is overlapped with the center of the corresponding color resist block D, and the size of the protruding structure 23 is smaller than the size of the corresponding color resist block D. In this case, the protruding structure 23 as a whole faces the corresponding color resist block D, and more light is collected and converged by the protruding structure 23. The center region of the protruding structure 23 with a smaller roughness causes light to be converged towards the front light-emitting direction, and thus the center region of the protruding structure 23 can increase the brightness in the front viewing angle direction. The edge region of the protruding structure 23 with a greater roughness causes light to deviate from the front light-emitting direction, and thus the edge region of the protruding structure 23 can increase the viewing angle. The light-emitting unit 22, the color resist block D corresponding to the light-emitting unit 22, and the protruding structure 23 corresponding to the light-emitting unit 22 form a light-emitting structure, and the light-emitting structure can achieve the effect of increasing the viewing angle of the display panel.

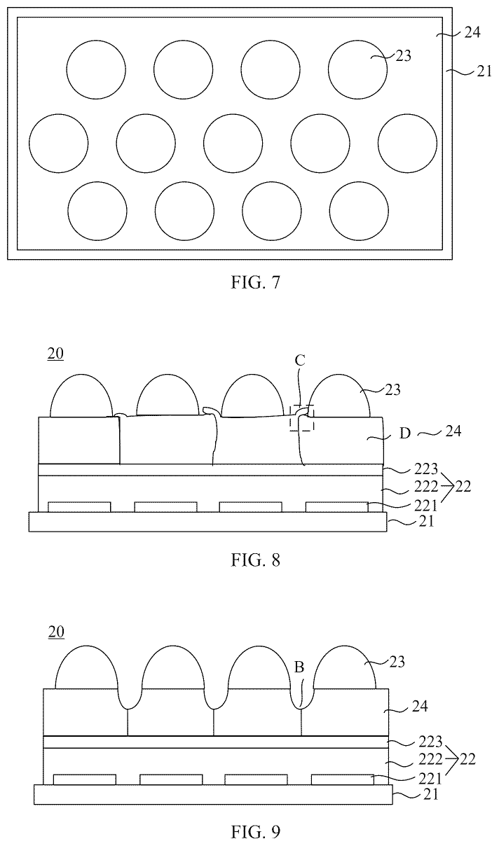

The plurality of color resist blocks D in the color film layer 24 are arranged in strips, dots, triangles, mosaics, or other specific patterns. The strip arrangement and the dot arrangement are suitable to large size and high fineness products, and the triangle arrangement and the mosaic arrangement are suitable to small size and low fineness products. When each protruding structure 23 corresponds to one color resist block D, the arrangement of the protruding structures 23 is consistent with the arrangement of the color resist blocks D. In some embodiments, the protruding structures 23 are arranged in strips, dots, triangles, mosaics, or other specific patterns. For the dot arrangement, please refer to FIG. 7, and FIG. 7 is a schematic diagram of a top view structure of a display panel including protruding structures arranged in dots. The plurality of protruding structures 23 are disposed on the side of the color film layer 24 away from the base 21, and the plurality of protruding structures 23 are arranged in dots. In order to clearly illustrate the arrangement of the protruding structures, FIG. 7 does not show the plurality of light-emitting units, and the plurality of light-emitting units may be arranged in a similar manner as the plurality of protruding structures 23, which is not limited in the embodiments of the present disclosure.

The surface of the color resist block according to the embodiments of the present disclosure may is in a protrusion shape. Referring to FIG. 8, which is a schematic structural diagram of another display panel including color resist blocks in a protrusion shape according to some embodiments of the present disclosure, a protrusion as shown in region C is generated on the side of the color resist block D away from the base 21. The protrusion affects the flatness of the surface of the color film layer 24 away from the base 21, resulting in color shift, i.e., in the side viewing angle, there is a difference in the light-emitting effects of different colors of color filters. The protrusion in region C may be generated due to the limitation on the manufacturing process of the color resist block D. Different colors of color resist blocks D are formed in several times, and therefore, after a color resist block D formed later fills the gap, an excess color resist material covers the boundary region of adjacent color resist blocks D, thereby forming the protrusion shape shown in region C.

In the embodiments of the present disclosure, a plurality of first pits are formed in the color film layer to prevent the protrusion shown in region C from affecting the flatness of the surface of the color film layer 24 away from the base 21. Referring to FIG. 9, which is a schematic structural diagram of a display panel provided with first pits according to some embodiments of the present disclosure, the display panel 20 includes a base 21, a plurality of light-emitting units 22, a plurality of light-transmitting protruding structures 23, and a color film layer 24. The plurality of light-emitting units include a first electrode layer 221, a light-emitting layer 222, and a second electrode layer 223.

A plurality of first pits B are formed in the color film layer 24, and the first pit B is between two adjacent protruding structures 23 of the plurality of protruding structures 23 disposed on the color film layer 24. Since the protruding structures 23 are manufactured by a dry-etching process, a portion of the color film layer 24 disposed between adjacent protruding structures 23 is etched due to the over-etching during the manufacturing process of the protruding structures 23, thereby forming the first pit B. The first pits B can remove the protrusions on the upper surface of the side, away from the base 21, of the color film layer 24, thereby preventing the protrusions from affecting the flatness of the surface of the color film layer 24 away from the base 21.

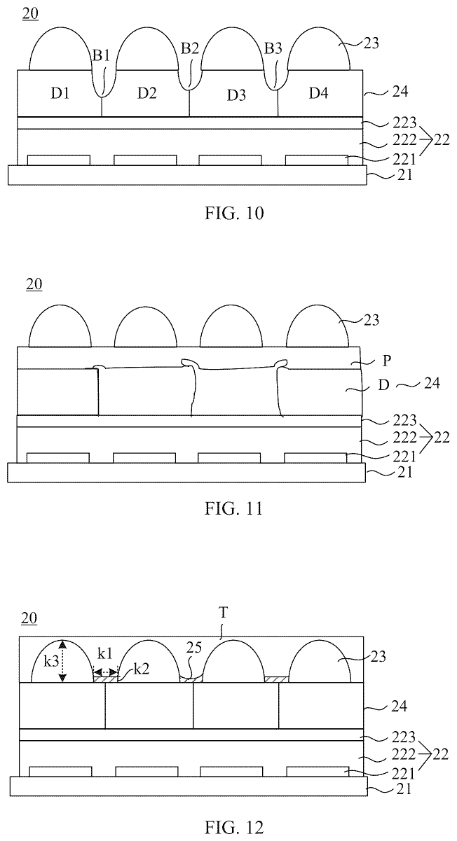

In some embodiments, the plurality of color resist blocks in the color film layer include at least three colors of color resist blocks, the first pit is disposed in a junction region of two adjacent color resist blocks of the three colors of color resist blocks, and the first pits in different junction regions of the two colors of color resist blocks have different depths. The junction region is a region covering the junction of two adjacent color resist blocks. In some embodiments, referring to FIG. 10, which is a schematic structural diagram of a display panel including three colors of color resist blocks, the display panel 20 includes three colors of color resist blocks. The color resist block D1 and the color resist block D4 are red, the color resist block D2 is green, and the color resist block D3 is blue. In the embodiments of the present disclosure, more than three colors of color resist blocks may also be provided, and the different colors of color resist blocks may also be arranged in other orders, which is not limited in the present disclosure. The color of the color resist block is determined by the chroma and transmittance of the color resist material of the color resist block.

Additionally, the display panel shown in FIG. 10 includes three first pits B. The first pit B1 is in the junction region of the red color resist block D1 and the green color resist block D2, the first pit B2 is in the junction region of the green color resist block D2 and the blue color resist block D3, and the first pit B3 is in the junction region of the blue color resist block D3 and the red color resist block D4. The junction region is a region covering the junction of two adjacent color resist blocks. The three first pits B are in different junction regions of two colors of color resist blocks D, and the first pit B1, the first pit B2, and the first pit B3 have different depths. In some embodiments, the first pit B1 is deeper than the first pit B2 and the first pit B3. This is because the color resist materials of the different colors of color resist blocks D have different etching rates. The faster the etching rate of the color resist material of the color resist block D, the deeper the corresponding first pit B.

In some embodiments, the first pits are arcuate first pits. In some embodiments, the first pits shown in FIG. 9 and FIG. 10 are arcuate first pits. The first pits may also be in other shapes, e.g., a triangle. The shape of the first pit is related to the parameters of the etching process, and is not limited in the embodiments of the present disclosure. In addition, since the first pit is in the junction region of different two colors of color resist blocks, and the two colors of color resist blocks have different etching rates, the bottom of each first pit is not flat and there is a difference in height.

In some embodiments, in the embodiments of the present disclosure, the color film layer 24 is covered with a planarization layer to increase the flatness of the color film layer. Referring to FIG. 11, which is a schematic structural diagram of a display panel including a planarization layer, the display panel 20 includes a planarization layer P. The planarization layer P is disposed between the color film layer 24 and the plurality of light-transmitting protruding structures 23, and the planarization layer P covers the protrusions on the upper surface of the side, away from the base 21, of the color film layer 24, thereby preventing the protrusions prevented from affecting the flatness of the surface of the color film layer 24 away from the base 21. The thickness of the planarization layer P may be less than a half of an average thickness of the color film layer 24, which is not limited in the embodiments of the present disclosure.

In some embodiments of the present disclosure, the display panel further includes a plurality of first etch-resistant blocks for preventing the color film layer from being etched. Referring to FIG. 12, which is a schematic structural diagram of a display panel including a plurality of first etch-resistant blocks, the display panel 20 includes a base 21, a plurality of light-emitting units 22, a plurality of light-transmitting protruding structures 23, and a color film layer 24. The plurality of light-emitting units 22 include a first electrode layer 221, a light-emitting layer 222, and a second electrode layer 223.

The display panel 20 further includes a plurality of first etch-resistant blocks 25, and the first etch-resistant block 25 is disposed between two adjacent protruding structures 23 of the plurality of protruding structures 23 disposed on the color film layer 24. The first etch-resistant block 25 has a smaller etching rate than the protruding structure 23, and thus the first etch-resistant block 25 can prevent the color film layer 24 disposed between two adjacent protruding structures 23 from being over-etched when the plurality of protruding structures 23 disposed on the color film layer 24 are etched.

In some embodiments, the material of the first etch-resistant block 25 includes a light-shielding material. In some embodiments, the first etch-resistant block 25 is of a black matrix (BM) structure, and the material of the first etch-resistant block 25 includes a titanium material. The titanium material has poor light transmittance, which is generally less than 2%. Therefore, the first etch-resistant block 25 can block the light between two adjacent protruding structures 23, thereby preventing the light between the two adjacent protruding structures 23 from crosstalk. The first etch-resistant block 25 can improve the display effect of the display panel 20, and the first etch-resistant block 25 has both the function of preventing the color film layer from being etched and the function of preventing light from crosstalk, thereby achieving the effect of simplifying the structure of the display panel.

Additionally, the width k1 of the first etch-resistant block 25 in the direction parallel to the base 21 is equal to the spacing between the two adjacent protruding structures 23 in the direction parallel to the base 21, thereby effectively blocking the light between the two adjacent protruding structures 23. In some embodiments, the width k1 of the first etch-resistant block 25 in the direction parallel to the base 21 is in the range of 0.4 μm to 1 μm. The thickness k2 of the first etch-resistant block 25 in the direction perpendicular to the base 21 is less than 10% of the thickness k3 of the protruding structure 23 in the direction perpendicular to the base 21, thereby preventing the first etch-resistant block 25 from being too thick to affect the flatness of the upper surface of the protruding structure 23. In some embodiments, the thickness k2 of the first etch-resistant block 25 in the direction perpendicular to the base 21 is greater than 500 angstroms (Å), and the thickness k3 of the protruding structure 23 in the direction perpendicular to the base 21 is 1.2 μm.

In some embodiments, the surface of the first etch-resistant block away from the base is an arcuate surface recessed towards the base, and the display panel further includes a light-transmitting layer. The light-transmitting layer is disposed on the surface of the first etch-resistant block away from the base, and the refractive index of the first etch-resistant block is less than the refractive index of the light-transmitting layer. Referring to FIG. 12, the surface of the first etch-resistant block 25 away from the base 21 is an arcuate surface recessed towards the base 21, and the light-transmitting layer T is disposed on the surface of the first etch-resistant block 25 away from the base 21. Since the refractive index of the first etch-resistant block 25 is less than the refractive index of the light-transmitting layer T, the angle of incidence of the light reaching the arcuate surface of the first etch-resistant block 25 is greater than the angle of emergence thereof, and the arcuate surface is recessed towards the base 21. Therefore, the first etch-resistant block 25 and the light-transmitting layer T form a convergent lens, and the light reaching the arcuate surface of the first etch-resistant block 25 can be converged, thereby preventing the light between the two adjacent protruding structures 23 from crosstalk. Thus, the first etch-resistant block 25 can improve the display effect of the display panel 20.

It should be noted that FIG. 12 shows that one first etch-resistant block 25 has an arcuate surface. In the embodiments of the present disclosure, the surfaces of all the first etch-resistant blocks 25 away from the base 21 may be arcuate surfaces recessed towards the base 21, which is not limited in the embodiments of the present disclosure.

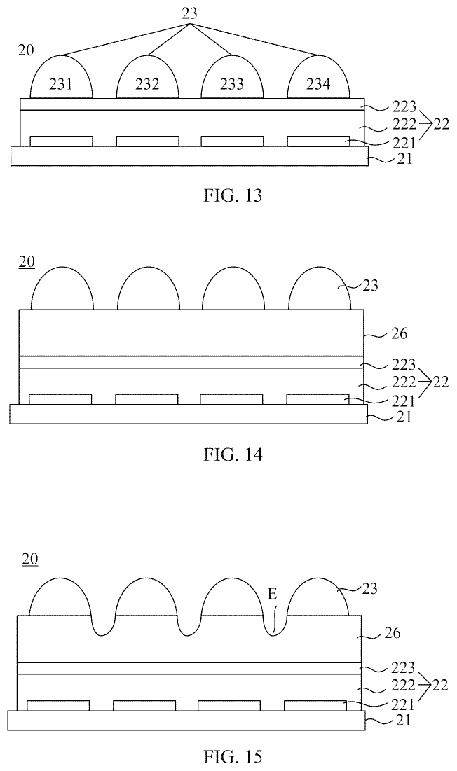

In the embodiments of the present disclosure, in addition to the above-described structure that the protruding structure is disposed independently of the color film layer, the material of the protruding structure may include a color resist material, and the plurality of protruding structures are reused as a color film layer, to simplify the structure and reduce the process processes. Referring to FIG. 13, which is a schematic structural diagram of a display panel in which the plurality of protruding structures are reused as a color film layer, the display panel 20 includes a base 21, a plurality of light-emitting units 22, and a plurality of light-transmitting protruding structures 23. The plurality of light-emitting units include a first electrode layer 221, a light-emitting layer 222, and a second electrode layer 223.

The material of the protruding structure 23 includes a color resist material, and the plurality of protruding structures 23 are reused as the color film layer, i.e., the protruding structures 23 also have the same function as the color film layer. The protruding structures 23 can filter the light generated by the light-emitting units 22, thereby acquiring light of the same color as the corresponding protruding structure 23 in the plurality of protruding structures 23. In some embodiments, different light-emitting units 22 emit different colors of light, each light-emitting unit 22 has the same color as the corresponding protruding structure 23, and the corresponding protruding structure 23 can filter light to improve the purity of the color of the light. Alternatively, the light-emitting units 22 emit white light, and the protruding structure 23 corresponding to each light-emitting unit 22 filters the white light into light of the same color as the protruding structure 23, e.g., red, blue, or green. Meanwhile, the protruding structures 23 can also adjust the brightness and viewing angle of the display panel.

In the case that the protruding structure is disposed independently of the color film layer, the protruding structure needs to be matched with the color film layer, which increases the process difficulty and the thickness of the display panel. FIG. 13 shows a display panel in which the protruding structures are reused as a color film layer. In this case, on the one hand, the manufacturing process can be simplified and the process difficulty can be reduced, thereby shortening the production cycle and reducing the cost of the product, and on the other hand, the thickness of the display panel can be reduced, which is conducive to the thinness of the display panel.

In some embodiments, the materials of the plurality of protruding structures include at least three colors of color resist materials. The roughness of the protruding structure corresponds to the color of the color resist material, and different colors correspond to different roughnesses. In some embodiments, referring to FIG. 13, the display panel 20 includes three colors of protruding structures 23, the protruding structure 231 and protruding structure 234 are reused as red color resistors, the protruding structure 232 is reused as a green color resistor, and the protruding structure 233 is reused as a blue color resistor. In the embodiments of the present disclosure, more than three colors of protruding structures may also be provided, which is not limited in the present disclosure.

Additionally, due to different materials, different colors of the light-emitting units have different light-emitting efficiencies. On this basis, in the embodiments of the present disclosure, the roughness of the protruding structure can be adjusted based on the light-emitting efficiencies of the different colors of light-emitting units. In some embodiments, in the multiple colors of light-emitting units, the light-emitting efficiency of a first color of light-emitting unit is positively correlated with the roughness of the protruding structure corresponding to the first color of light-emitting unit. That is, the higher the light-emitting efficiency of the light-emitting unit of a color, the greater the roughness of the protruding structure corresponding to the light-emitting unit of that color (the roughness refers to the average value of the roughnesses in the edge region of the protruding structure). In this way, the brightness at a bigger viewing angle can be improved under the premise of ensuring certain brightness at the front viewing angle.

In some embodiments, the light-emitting unit 22 corresponding to the protruding structure 233 is a blue light-emitting unit, and the blue light-emitting unit has a lower light-emitting efficiency. Therefore, the roughness of the protruding structure 233 corresponding to the blue light-emitting unit is smaller than the roughnesses of the protruding structure 231, the protruding structure 232, and the protruding structure 234 that correspond to the light-emitting units of other colors, thereby increasing the brightness of the blue light-emitting unit in the front viewing angle direction, and preventing the brightness in the front viewing angle direction from being too low due to the lower light-emitting efficiency of the blue light-emitting unit. The roughness of the protruding structure 23 is an average roughness of the surface of the side, away from the base 21, of the protruding structure 23 or a maximum value of the roughnesses at various positions of the surface of the side, away from the base 21, of the protruding structure 23. Because different colors of color resist materials have different etching rates, the different colors of protruding structures 232 have different thicknesses in the direction perpendicular to the base 21.

On the basis of the above display panel in which the protruding structures are reused as the color film layer, the display panel according to the embodiments of the present disclosure further includes an encapsulation layer. Referring to FIG. 14, which is a schematic structural diagram of a display panel including an encapsulation layer according to some embodiments of the present disclosure, the display panel 20 includes a base 21, a plurality of light-emitting units 22, a plurality of light-transmitting protruding structures 23, and an encapsulation layer 26. The plurality of light-emitting units include a first electrode layer 221, a light-emitting layer 222, and a second electrode layer 223. The material of the protruding structure 23 includes a color resist material, and the plurality of protruding structures 23 are reused as the color film layer.

The encapsulation layer 26 is disposed on the side of the plurality of light-emitting units 22 away from the base 21, and the plurality of protruding structures 23 are disposed on the encapsulation layer 26. The encapsulation layer 26 covers the plurality of light-emitting units 22 to prevent external moisture or oxygen from penetrating into the plurality of light-emitting units 22. The encapsulation layer 26 further includes an organic encapsulation layer and an inorganic encapsulation layer, thereby effectively improving the encapsulation effect. In some embodiments, the encapsulation layer 26 is of a three-layer structure including silicon nitride (SiN), aluminum oxide (Al₂O₃), and silicon nitride (SiN).

In some embodiments, a plurality of second pits are formed in the encapsulation layer. Referring to FIG. 15, which is a schematic structural diagram of a display panel provided with second pits according to some embodiments of the present disclosure, a plurality of second pits E are formed in the encapsulation layer 26, and the second pit E is between two adjacent projecting structures 23 of the plurality of projecting structures 23 disposed on the encapsulation layer 26. Since the protruding structures 23 are manufactured by a dry-etching process, a portion of the encapsulation layer 26 disposed between two adjacent protruding structures 23 is etched due to the over-etching during the manufacturing process of the protruding structures 23, thereby forming the second pit E.

Additionally, the edge of the second pit E and the edge of the protruding structure 23 are smoothly connected, which can improve the smoothness at the connection between the second pit E and the protruding structure 23, thereby improving the light-emitting uniformity and the display effect of the display panel 20.

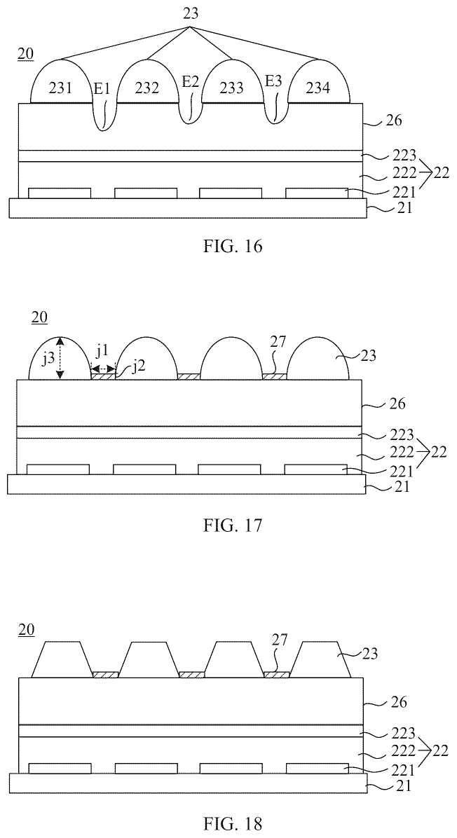

In some embodiments, the plurality of color resist blocks in the color film layer include at least three colors of color resist blocks, and the second pits between different two colors of color resist blocks have different depths, that is, the protruding structures 23 include at least three colors of protruding structures 23, and the second pits between different two colors of protruding structures 23 have different depths. In some embodiments, referring to FIG. 16, which is a schematic structural diagram of a display panel including three colors of protruding structures, the display panel 20 includes three colors of protruding structures 23; the protruding structure 231 and the protruding structure 234 are red, the protruding structure 232 is green, and the protruding structure 233 is blue. In the embodiments of the present disclosure, more than three colors of protruding structures may also be provided, which is not limited in the present disclosure.

Additionally, the display panel shown in FIG. 16 is provided with three second pits E. The second pit El is disposed between the red protruding structure 231 and the green protruding structure 232, the second pit E2 is disposed between the green protruding structure 232 and the blue protruding structure 233, and the second pit E3 is disposed between the blue protruding structure 233 and the red protruding structure 234. The three second pits E are disposed between different two colors of protruding structures 23, and the second pit E1, the second pit E2, and the second pit E3 have different depths. In some embodiments, the second pit El is deeper than the second pit E2 and the second pit E3. This is because the color resist materials of the different colors of protruding structures 23 have different etching rates. The faster the etching rate of the material of the protruding structure 23, the deeper the corresponding second pit E.

On the basis of the above display panel in which the protruding structures are reused as the color film layer, the display panel further includes a plurality of second etch-resistant blocks to improve the encapsulation effect. Referring to FIG. 17, which is a schematic structural diagram of a display panel including a plurality of second etch-resistant blocks, the display panel 20 includes a base 21, a plurality of light-emitting units 22, a plurality of light-transmitting protruding structures 23, and an encapsulation layer 26. The plurality of light-emitting units include a first electrode layer 221, a light-emitting layer 222, and a second electrode layer 223. The material of the protruding structure 23 includes a color resist material, and the plurality of protruding structures 23 are reused as the color film layer.

The display panel 20 further includes a plurality of second etch-resistant blocks 27, and the second etch-resistant block 27 is disposed between two adjacent protruding structures 23 of the plurality of protruding structures 23. The second etch-resistant block 27 can prevent the encapsulation layer 26 disposed between two adjacent protruding structures 23 from being over-etched when the plurality of protruding structures 23 disposed on the encapsulation layer 26 are etched, thereby ensuring the encapsulation effect. The second etch-resistant blocks 27 can improve the encapsulation effect of the display panel 20.

In some embodiments, the material of the second etch-resistant block 27 includes a light-shielding material. In some embodiments, the second etch-resistant block 27 is of a black matrix structure, and the material of the second etch-resistant block 27 includes a titanium material. The titanium material has poor light transmittance, which is generally less than 2%. Therefore, the second etch-resistant block 27 can block the light between two adjacent protruding structures 23, thereby preventing the light between the two adjacent protruding structures 23 from crosstalk. The second etch-resistant block 27 can improve the display effect of the display panel 20, and the second etch-resistant block 27 has both the function of preventing the encapsulation layer from being etched and the function of preventing light from crosstalk, thereby achieving the effect of simplifying the structure of the display panel.

Additionally, the width j1 of the second etch-resistant block 27 in the direction parallel to the base 21 is equal to the spacing between the two adjacent protruding structures 23 in the direction parallel to the base 21, thereby effectively blocking the light between the two adjacent protruding structures 23. In some embodiments, the width j1 of the second etch-resistant block 27 in the direction parallel to the base 21 is in the range of 0.4 μm to 1 μm. The thickness j2 of the second etch-resistant block 27 in the direction perpendicular to the base 21 is less than 10% of the thickness j3 of the protruding structure 23 in the direction perpendicular to the base 21, thereby preventing the second etch-resistant block 27 from being too thick to affect the flatness of the upper surface of the protruding structure 23. In some embodiments, the thickness j2 of the second etch-resistant block 27 in the direction perpendicular to the base 21 is greater than 500 Å, and the thickness j3 of the protruding structure 23 in the direction perpendicular to the base 21 is 1.2 μm.

In the embodiments of the present disclosure, the protruding structure is in a plurality of shapes, and the protruding structure may be in a convex lens shape. The size of the protruding structure is negatively correlated with the average roughness of the edge region. In some embodiments, in the display panels shown in FIG. 3 to FIG. 17, the protruding structure 23 is the convex lens shape, and the convex lens shape can effectively improve the light-converging effect. The convex lens shape of the protruding structure 23 is acquired by a thermal reflow process and a dry-etching process. Through the thermal reflow process, a photoresist undergoes a physical change after being subjected to heat, and the photoresist forms a curved convex lens shape under the action of surface tension. The temperature used in the thermal reflow process is greater than a critical temperature at which the photoresist undergoes the physical change. In some embodiments, the temperature used in the thermal reflow process is in a range of 90° C. to 110° C. The plurality of protruding structures in the convex lens shape are acquired by transferring the shape of the photoresist in the convex lens shape to a light-transmitting material or a color film layer by a dry-etching process.

Additionally, the average roughness of the protruding structure 23 is also correlated with the size of the protruding structure 23 (the size is a size of the orthographic projection of the protruding structure 23 on the base 21), and the average roughness is an average value of the roughnesses at various positions of the surface of the side, away from the base 21, of the protruding structure 23. In some embodiments, the size of the protruding structure 23 is negatively correlated with the average roughness of the edge region A2, i.e., the smaller the size of the protruding structure 23, the greater the average roughness of the edge region A2. Thus, the average roughness of the edge region A2 can be determined based on the size of the protruding structure 23 without the need to conduct a complicated test and calculation of the average roughness. In some embodiments, in the case that the protruding structure 23 is a hemispherical convex lens, the size of the protruding structure 23 is the radius of the orthographic projection of the protruding structure 23 on the base 21, and the radius of the protruding structure 23 is negatively correlated with the average roughness of the edge region A2.

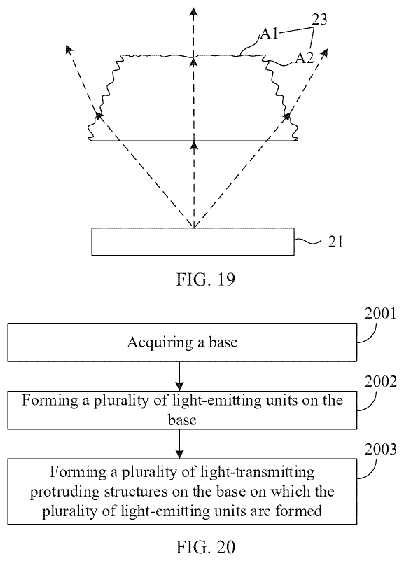

In some embodiments, in addition to the convex lens shape, the protruding structure according to the embodiments of the present disclosure may also be in the shape of a trapezoidal protrusion. In some embodiments, referring to FIG. 18 and FIG. 19, which are a schematic structural diagram of a display panel including protruding structures in the shape of a trapezoid and a schematic diagram of light emission of the display panel provided in FIG. 18 respectively, the display panel 20 includes a base 21, a plurality of light-emitting units 22, a plurality of light-transmitting protruding structures 23, an encapsulation layer 26, and a plurality of second etch-resistant blocks 27. The plurality of light-emitting units include a first electrode layer 221, a light-emitting layer 222, and a second electrode layer 223. The material of the protruding structure 23 includes a color resist material, and the plurality of protruding structures 23 are reused as the color film layer.

The plurality of protruding structures 23 are trapezoidal protrusions, and the upper surface of the trapezoidal protrusion is disposed on the side of the lower surface away from the base 21. The protruding structure 23 has a center region A1 and an edge region A2 outside the center region A1. The center region A1 of the protruding structure 23 is a top surface of the trapezoidal protrusion where the upper surface is located, and the edge region A2 of the protruding structure 23 is a side surface of the trapezoidal protrusion. Alternatively, the center region A1 of the protruding structure 23 is a partial region of the top surface of the trapezoidal protrusion, and the edge region A2 is a side surface of the trapezoidal protrusion and other regions of the top surface of the trapezoidal protrusion, which is not limited in the embodiments of the present disclosure. The roughness of the center region A1 is smaller than the roughness of the edge region A2, and the center of the orthographic projection of the protruding structure 23 on the base 21 is within the orthographic projection of the center region A1 on the base 21.

The protruding structure 23 in the shape of a trapezoidal protrusion may also be acquired by transferring the shape of a protruding structure model to a light-transmitting material layer by an etching process. In some embodiments, the etching process includes a dry-etching process. The thickness of the protruding structure model in the edge region is less than the thickness of the protruding structure model in the center region, and thus the over-etching amount in the edge region of the light-transmitting material layer is larger than the over-etching amount in the center region, that is, the edge region is subjected to more etching, and the manufactured protruding structure 23 has a greater roughness in the edge region A2 than in the center region A1. The center region A1 is smoother than the edge region A2, the center region A1 can ensure a certain brightness in the front viewing angle direction, and the edge region A2 can increase the viewing angle. The center region A1 and the edge region A2 of the protruding structure 23 both have a certain light-converging effect, the center region A1 with a smaller roughness can converge light to the front viewing angle direction, and the edge region A2 with a greater roughness can converge light to directions other than the front viewing angle direction, thereby increasing the viewing angle.

In the embodiments of the present disclosure, a pixel defining layer is further provided between the base and the light-emitting layer. The pixel defining layer covers the edge of the first electrode of each of the light-emitting units, and the pixel defining layer is configured to define the positions of the plurality of light-emitting units in the display panel on the base.

In summary, the embodiments of the present disclosure provide a display panel including a base, a plurality of light-emitting units, and a plurality of light-transmitting protruding structures. The protruding structure has a center region and an edge region outside the center region, and the roughness of the center region is smaller than the roughness of the edge region. With this structure, light emitted from the plurality of light-emitting units can be converged by the protruding structures. Since the protruding structure has a greater roughness in the edge region, the light-converging capability of the edge region can be reduced, and the viewing angle of the display panel can be increased while ensuring a certain brightness in the front viewing angle direction, thereby solving the problem of the small viewing angle of the display panel in the related art and achieving the effect of improving the viewing angle of the display panel.

In another aspect, some embodiments of the present disclosure provide a method for manufacturing a display panel. Referring to FIG. 20, which is a flowchart of a method for manufacturing a display panel, the method includes the following processes.

In 2001, a base is acquired.

In 2002, a plurality of light-emitting units are formed on the base.

In 2003, a plurality of light-transmitting protruding structures are formed on the base on which the plurality of light-emitting units are formed. The plurality of protruding structures are disposed on the side of the plurality of light-emitting units away from the base. The protruding structure has a center region and an edge region outside the center region, and the roughness of the center region is smaller than the roughness of the edge region. A center of the orthographic projection of the protruding structure on the base is within the orthographic projection of the center region on the base.

In summary, the embodiments of the present disclosure provide a display panel including a base, a plurality of light-emitting units, and a plurality of light-transmitting protruding structures. The protruding structure has a center region and an edge region outside the center region, and the roughness of the center region is smaller than the roughness of the edge region. With this structure, light emitted from the plurality of light-emitting units can be converged by the protruding structures. Since the protruding structure has a greater roughness in the edge region, the light-converging capability of the edge region can be reduced, and the viewing angle of the display panel can be increased while ensuring a certain brightness in the front viewing angle direction, thereby solving the problem of the small viewing angle of the display panel in the related art and achieving the effect of improving the viewing angle of the display panel.

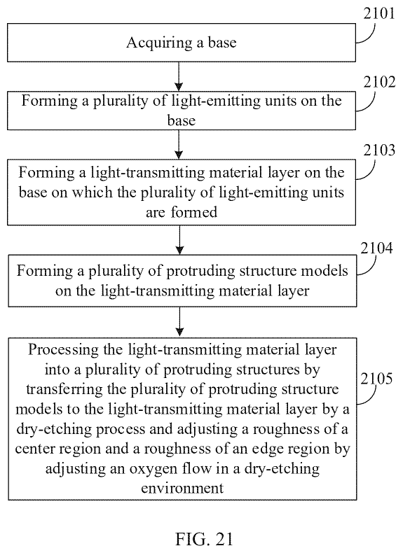

Some embodiments of the present disclosure provide another method for manufacturing a display panel. Referring to FIG. 21, which is a flowchart of another method for manufacturing a display panel, the method includes the following processes.

In 2101, a base is acquired.

The base is provided as a substrate for other film layers in the display panel to improve the flatness of the other film layers, and the base is cleaned and baked before use.

In 2102, a plurality of light-emitting units are formed on the base.

A plurality of light-emitting units are formed on the base. The plurality of light-emitting units include a first electrode layer, a light-emitting layer, and a second electrode layer, and the first electrode layer and the second electrode layer cooperate with each other to drive the light-emitting layer. The first electrode layer is an anode, the second electrode layer is a cathode, and the light-emitting layer is an organic light-emitting layer.

In 2103, a light-transmitting material layer is formed on the base on which the plurality of light-emitting units are formed.

A light-transmitting material layer is formed on the base on which the plurality of light-emitting units are formed. The light-transmitting material layer is used for forming a protruding structure having a light-converging function, and thus the material of the light-transmitting material layer transmits light emitted from the light-emitting units. Exemplary, the material of the light-transmitting material layer includes polydimethylsiloxane (PDMS), polymethyl methacrylate (PMMA), and silicon dioxide (SiO₂).

In 2104, a plurality of protruding structure models are formed on the light-transmitting material layer.

A plurality of protruding structure models are formed on the light-transmitting material layer. The plurality of protruding structure models correspond to at least one of a plurality of color resist blocks, that is, each protruding structure model corresponds to one or more color resist blocks. The protrusions of the plurality of protruding structure models face away from the base, and the materials of the plurality of protruding structure models includes a photoresist (PR).

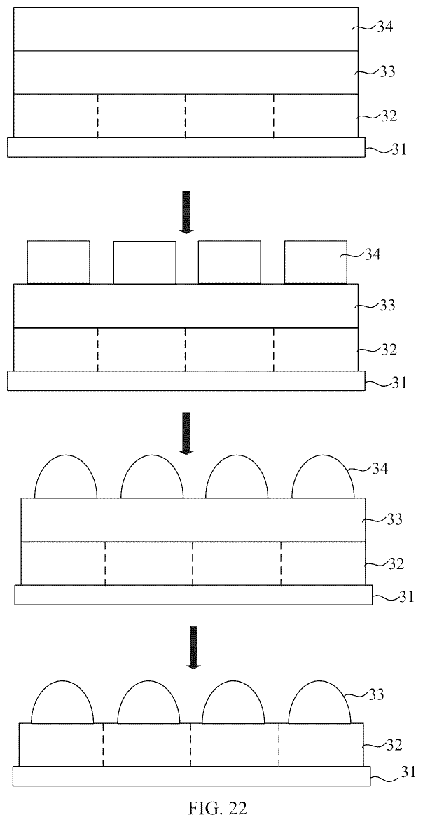

The plurality of protruding structure models are in a convex lens shape or a trapezoidal protrusion shape. In the case that the plurality of protruding structure models are in the convex lens shape, referring to FIG. 22, which is a schematic diagram of a manufacturing process of a protruding structure in the convex lens shape, the light-transmitting material layer 33 is disposed on the base 31 on which the plurality of light-emitting units 32 are formed, and the photoresist 34 is coated on the side of the light-transmitting material layer 33 away from the base 31. The square photoresist 34 corresponding to the plurality of light-emitting units 32 is acquired by exposure and development, and then the plurality of protruding structure models in the convex lens shape are acquired by a thermal reflow process. Through the thermal reflow process, the photoresist 34 undergoes a physical change after being subjected to heat, and the square photoresist 34 forms a curved convex lens shape under the action of surface tension. The temperature used in the thermal reflow process is greater than a critical temperature at which the photoresist undergoes the physical change. In some embodiments, the temperature used in the thermal reflow process is in a range of 90° C. to 110° C.

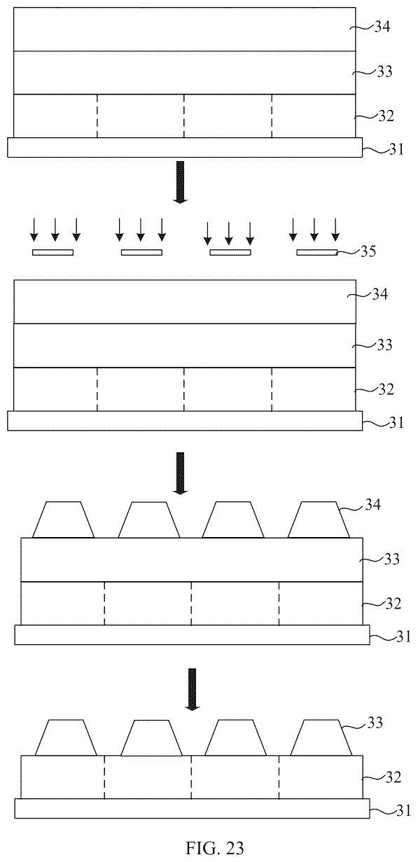

In the case that the plurality of protruding structure models are in the trapezoidal protrusion shape, referring to FIG. 23, which is a schematic diagram of a manufacturing process of a protruding structure in a trapezoidal protrusion shape, the light-transmitting material layer 33 is disposed on the base 31 on which the plurality of light-emitting units 32 are formed, and the photoresist 34 is coated on the light-transmitting material layer 33. The plurality of protruding structure models 34 in the trapezoidal protrusion shape are acquired using a positive photoresist 35 as an etching barrier layer by exposure in which the focus is adjusted and development.

In 2105, the light-transmitting material layer is processed into a plurality of protruding structures by transferring the plurality of protruding structure models to the light-transmitting material layer by a dry-etching process and adjusting a roughness of a center region and a roughness of an edge region by adjusting an oxygen flow in a dry-etching environment.

The transfer of the plurality of protruding structure models to the light-transmitting material layer is achieved by the dry-etching process. The basic principle of the dry-etching process is to process the surface of the material using high-energy ion beams or plasma to form a desired pattern or structure. Referring to FIG. 22 and FIG. 23, according to the embodiments of the present disclosure, the light-transmitting material layer 33 is processed into the plurality of protruding structures 34 in the convex lens shape or the trapezoidal protrusion shape by the dry-etching process.

Additionally, the roughness of the center region and the roughness of the edge region are adjusted by adjusting the oxygen flow in the dry-etching environment. Specifically, the higher the oxygen flow is, the faster the plurality of protruding structure models are removed, the larger the over-etching amount of the light-transmitting material layer is, and the greater the roughness of the center region and the roughness of the edge region of each of the plurality of protruding structures are.

Additionally, the oxygen flow used may also be determined by calculating an etching selectivity ratio of the material of the protruding structure model to the material of the light-transmitting material layer, and the etching selectivity ratio is a ratio of an etching rate of the material of the protruding structure model to an etching rate of the material of the light-transmitting material layer. The bigger the etching selectivity ratio, the faster the etching rate of the protruding structure model, the larger the over-etching amount of the light-transmitting material layer, and the bigger the oxygen flow to be used, which is not limited in the embodiments of the present disclosure. Since the thickness of the protruding structure model in the edge region is less than the thickness of the protruding structure model in the center region, the over-etching amount of the light-transmitting material layer in the edge region is greater than the over-etching amount in the center region, that is, the edge region is subjected to more etching, and the manufactured protruding structure has a greater roughness in the edge region than in the center region.

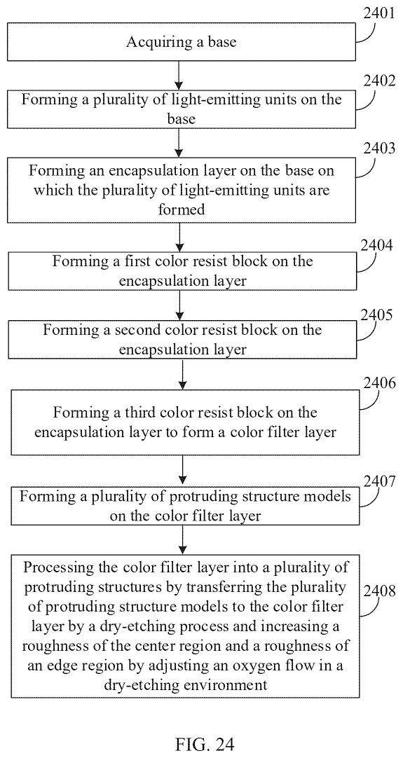

The display panel according to the embodiments of the present disclosure further includes an encapsulation layer and a color film layer, and the materials of the plurality of protruding structures include a color resist material and are reused as a color film layer. Referring to FIG. 24, which shows a method for manufacturing a display panel in which the protruding structures are reused as the color film layer, the method includes the following processes.

In 2401, a base is acquired.

The base is provided as a substrate for other film layers in the display panel to improve the flatness of the other film layers, and the base is cleaned and baked before use.

In 2402, a plurality of light-emitting units are formed on the base.

A plurality of light-emitting units are formed on the base. The plurality of light-emitting units include a first electrode layer, a light-emitting layer, and a second electrode layer, and the first electrode layer and the second electrode layer cooperate with each other to drive the light-emitting layer. The first electrode layer is an anode, the second electrode layer is a cathode, and the light-emitting layer is an organic light-emitting layer.

In 2403, an encapsulation layer is formed on the base on which the plurality of light-emitting units are formed.

An encapsulation layer is formed on the base on which the plurality of light-emitting units are formed. The encapsulation layer covers the plurality of light-emitting units to prevent external moisture or oxygen from penetrating into the plurality of light-emitting units. The encapsulation layer includes an organic encapsulation layer and an inorganic encapsulation layer, thereby effectively improving the encapsulation effect. In some embodiments, the encapsulation layer is of a three-layer structure including SiN, Al₂O₃, and SiN.

In 2404, a first color resist block is formed on the encapsulation layer.

A first color resist block is formed on the encapsulation layer. Specifically, the first color resist block is formed on the encapsulation layer by photoresist coating, exposure, and development. The first color resist block is one of green, blue, or red. The first color resist block may be of other colors, which is not limited in the embodiments of the present disclosure.

In 2405, a second color resist block is formed on the encapsulation layer.

A second color resist block is formed on the encapsulation layer. Specifically, the second color resist block is formed on the encapsulation layer by photoresist coating, exposure, and development. The second color resist block is adjacent to the first color resist block, and the second color resist block is of a color, which is different from the color of the first color resist block, of green, blue, or red. The second color resist block may be of other colors, which is not limited in the embodiments of the present disclosure.

In 2406, a third color resist block is formed on the encapsulation layer to form a color film layer.

A third color resist block is formed on the encapsulation layer. Specifically, the third color resist block is formed on the encapsulation layer by photoresist coating, exposure, and development. The third color resist block is adjacent to the second color resist block and the first color resist block, and the third color resist block is of a color, which is different from the color of the first color resist block and color of the second color resist block, of green, blue, or red. The third color resist block may be of other colors, which is not limited in the embodiments of the present disclosure.

Since the third color resist block is formed after the first color resist block and the second color resist block, after the third color resist block fills the gap, an excess color resist material covers the boundary region of the adjacent first color resist block and the boundary region of the adjacent second color resist block, thereby forming the protrusions as shown in region C of FIG. 8.

In 2407, a plurality of protruding structure models are formed on the color film layer.

A plurality of protruding structure models are formed on the color film layer. The protruding structure model correspond to at least one of the plurality of color resist blocks, i.e., each protruding structure model corresponds to one or more color resist blocks. The protrusions of the plurality of protruding structure models face away from the base, and the materials of the plurality of protruding structure models include a photoresist. The plurality of protruding structure models are in a convex lens shape or a trapezoidal protrusion shape. For the details of the manufacturing processes of the protruding structure models in different shapes, reference may be referred to the above-described embodiments, which are not repeated herein.

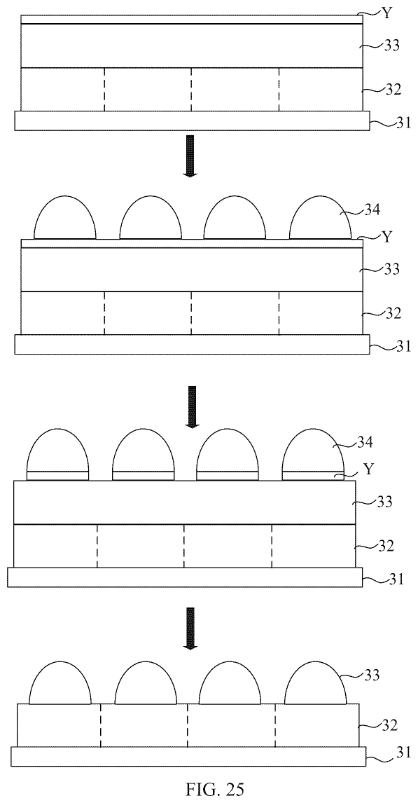

In some embodiments, a hard mask is provided on the color film layer before the plurality of protruding structure models are formed on the color film layer. Referring to FIG. 25, which is a schematic diagram of another manufacturing process of a protruding structure, the light-transmitting material layer 33 is disposed on the base 31 on which the plurality of light-emitting units 32 are formed, the hard mask Y covers a partial region of the light-transmitting material layer 33, the partial region of the light-transmitting material layer 33 is a region to be set as a center region in subsequent processes, and the protruding structure model 34 is disposed on the side of the hard mask Y away from the base 31. In this way, the hard mask Y can protect the partial region of the light-transmitting material layer 33 to prevent the roughness of the partial region from being increased due to the etching process adopted to transfer the shape of the protruding structure model 34 to the light-transmitting material layer 33 subsequently. Thus, the surface of this region is smoother, thereby improving the light-converging effect of the central region of the protruding structure, and increasing the brightness. The material of the hard mask Y includes silicon oxide (SiOx). The material of the hard mask Y may also include other etch-resistant materials, which is not limited in the embodiments of the present disclosure.

In 2408, the color film layer is processed into a plurality of protruding structures by transferring the plurality of protruding structure models to the color film layer by a dry-etching process and increasing a roughness of the center region and a roughness of an edge region by adjusting an oxygen flow in a dry-etching environment.

The transfer of the plurality of protruding structure models to the color film layer is achieved by the dry-etching process. The basic principle of the dry-etching process is to process the surface of the material using high-energy ion beams or plasma to form a desired pattern or structure. According to the embodiments of the present disclosure, the color film layer is processed into the plurality of protruding structures in the convex lens shape or the trapezoidal protrusion shape by the dry-etching process. In addition, the roughness of the center region and the roughness of the edge region are adjusted by adjusting the oxygen flow in the dry-etching environment. Specifically, the bigger the oxygen flow is, the faster the plurality of protruding structure models are removed, the larger the over-etching amount of the light-transmitting material layer is, and the greater the roughness of the center region and the roughness of the edge region of each of the plurality of acquired protruding structures are. In the case that the protruding structure is disposed independently of the color film layer, the protruding structure needs to be matched with the color film layer, which increases the process difficulty and the thickness of the display panel. Therefore, for the display panel in which the protruding structures are reused as the color film layer, on the one hand, the manufacturing process can be simplified and the process difficulty can be reduced, thereby shortening the production cycle and reducing the cost of the product, and on the other hand, the thickness of the display panel can be reduced, which is conducive to the thinness of the display panel.

In summary, the embodiments of the present disclosure provide a display panel including a base, a plurality of light-emitting units, and a plurality of light-transmitting protruding structures. The protruding structure has a center region and an edge region outside the center region, and the roughness of the center region is smaller than the roughness of the edge region. With this structure, light emitted from the plurality of light-emitting units can be converged by the protruding structures. Since the protruding structure has a greater roughness in the edge region, the light-converging capability of the edge region can be reduced, and the viewing angle of the display panel can be increased while ensuring a certain brightness in the front viewing angle direction, thereby solving the problem of the small viewing angle of the display panel in the related art and achieving the effect of improving the viewing angle of the display panel.

In still another aspect, some embodiments of the present disclosure provide a display device. The display device includes a power supply assembly and the display panel provided in the foregoing embodiments, and the power supply assembly supplies power to the display panel. The display device may be any device having a display function. For example, the display device is a micro-OLED display device, which is applicable to the field of virtual reality (VR) display and augmented reality (AR) display.

Since the display device includes the display panel provided in the foregoing embodiments, the display device can achieve similar effects as the display panel, i.e., improving viewing angle of the display device.

It should be noted that in the drawings, the dimensions of layers and regions may be exaggerated for clarity of illustration. It is to be further understood that when an element or layer is referred to as being “on” another element or layer, it may be directly on the element, or an intermediate layer may be present. Additionally, it is to be understood that when an element or layer is referred to as being “under” another element or layer, it may be directly under the element, or more than one intermediate layer or element may be present. It is to be further understood that when a layer or element is referred to as being “between” two layers or two elements, it may be the only layer between the two layers or two elements, or more than one intermediate layer or element may be present. Similar reference numerals indicate similar elements throughout.

In the present disclosure, the terms “first,” “second,” and “third” are used for descriptive purposes only and should not be construed as indicating or implying relative importance. The term “a plurality of” refers to two or more, unless otherwise expressly defined.

Described above are merely optional embodiments of the present disclosure, and are not intended to limit the present disclosure. Any modifications, equivalent substitutions, improvements and the like made within the spirit and principles of the present disclosure should be included in the protection scope of the present disclosure.

1. A display panel, comprising:
a base;
a plurality of light-emitting units disposed on the base; and
a plurality of light-transmitting protruding structures, wherein the plurality of protruding structures are disposed on a side of the plurality of light-emitting units away from the base, and the protruding structure has a center region and an edge region outside the center region, a roughness of the center region being smaller than a roughness of the edge region, and a center of an orthographic projection of the protruding structure on the base being within an orthographic projection of the center region on the base.

2. The display panel according to claim 1, wherein there is at least one of:
a roughness of the protruding structure decreases sequentially along a light-exiting direction of the light-emitting unit, the center region is a region with a roughness smaller than a target roughness, and the edge region is a region with a roughness greater than or equal to the target roughness; or
the protruding structure comprises a plurality of micro protruding structures disposed in the edge region.

3. The display panel according to claim 1, further comprising: a color film layer; wherein
the color film layer is disposed on the side of the plurality of light-emitting units away from the base, and the plurality of protruding structures are disposed on the color film layer; and
the color film layer comprises a plurality of color resist blocks, wherein the protruding structure corresponds to at least one of the plurality of color resist blocks, and the orthographic projection of the protruding structure on the base is overlapped with an orthographic projection of a corresponding color resist block on the base.

4. The display panel according to claim 3, wherein a plurality of first pits are formed in the color film layer; wherein
the first pit is disposed between two adjacent protruding structures of the plurality of protruding structures disposed on the color film layer.

5. The display panel according to claim 4, wherein the plurality of color resist blocks in the color film layer comprise at least three colors of color resist blocks; wherein
the first pit is disposed in a junction region of two adjacent color resist blocks of the three colors of color resist blocks, and the first pits in different junction regions of two colors of color resist blocks have different depths, wherein the junction region is a region comprising a junction of the two adjacent color resist blocks.

6. The display panel according to claim 4, wherein the first pit is an arcuate first pit.

7. The display panel according to claim 3, further comprising: a plurality of first etch-resistant blocks;
wherein the first etch-resistant block is disposed between two adjacent protruding structures of the plurality of protruding structures disposed on the color film layer.

8. The display panel according to claim 7, wherein a material of the first etch-resistant block comprises a light-shielding material.

9. The display panel according to claim 7, wherein a surface of the first etch-resistant block away from the base is an arcuate surface recessed towards the base; and
the display panel further comprises: a light-transmitting layer, wherein the light-transmitting layer is disposed on the surface of the first etch-resistant block away from the base, and a refractive index of the first etch-resistant block is less than a refractive index of the light-transmitting layer.

10. (canceled)

11. The display panel according to claim 1, wherein a material of the protruding structure comprises a color resist material, and the plurality of protruding structures are reused as a color film layer.

12. The display panel according to claim 11, wherein the plurality of protruding structures comprise at least three colors of color resist materials, the roughness of the protruding structure corresponds to a color of the color resist material, and different colors corresponding to different roughnesses.

13. The display panel according to claim 11, further comprising: an encapsulation layer; wherein
the encapsulation layer is disposed on the side of the plurality of light-emitting units away from the base, and the plurality of protruding structures are disposed on the encapsulation layer.

14. The display panel according to claim 13, wherein a plurality of second pits are formed in the encapsulation layer; wherein
the second pit is disposed between two adjacent protruding structures of the plurality of protruding structures disposed on the encapsulation layer.

15. The display panel according to claim 14, wherein an edge of the second pit is smoothly connected to an edge of the protruding structure.

16. The display panel according to claim 14, wherein a plurality of color resist blocks in a color film layer comprise at least three colors of color resist blocks, and the second pits disposed between different two colors of color resist blocks have different depths.

17. The display panel according to claim 11, further comprising: a plurality of second etch-resistant blocks; wherein
the second etch-resistant block is disposed between two adjacent protruding structures of the plurality of protruding structures, wherein a material of the second etch-resistant block comprises a light-shielding material.

18. (canceled)

19. The display panel according to claim 1, wherein the protruding structure is a convex lens, and a size of the protruding structure is negatively correlated with an average roughness of the edge region; or the protruding structure is a trapezoidal protrusion, wherein an upper surface of the trapezoidal protrusion is on a side of a lower surface away from the base.

20. (canceled)

21. A method for manufacturing a display panel, comprising:
acquiring a base;
forming a plurality of light-emitting units on the base; and
forming a plurality of light-transmitting protruding structures on the base on which the plurality of light-emitting units are formed, wherein the plurality of protruding structures are disposed on a side of the plurality of light-emitting units away from the base, and the protruding structure has a center region and an edge region outside the center region, a roughness of the center region being smaller than a roughness of the edge region, and a center of an orthographic projection of the protruding structure on the base being within an orthographic projection of the center region on the base.

22. The method according to claim 21, wherein forming the plurality of light-transmitting protruding structures on the base on which the plurality of light-emitting units are formed comprises:
forming a light-transmitting material layer on the base on which the plurality of light-emitting units are formed;
forming a plurality of protruding structure models on the light-transmitting material layer; and
processing the light-transmitting material layer into the plurality of protruding structures by transferring the plurality of protruding structure models to the light-transmitting material layer by a dry-etching process and adjusting the roughness of the center region and the roughness of the edge region by adjusting an oxygen flow in a dry-etching environment.

23. A display device, comprising; a power supply assembly and a, wherein the display panel comprises:
a base;
a plurality of light-emitting units disposed on the base; and
a plurality of light-transmitting protruding structures, wherein the plurality of protruding structures are disposed on a side of the plurality of light-emitting units away from the base, and the protruding structure has a center region and an edge region outside the center region, a roughness of the center region being smaller than a roughness of the edge region, and a center of an orthographic projection of the protruding structure on the base being within an orthographic projection of the center region on the base.
